(19) United States
(12) Patent Application Publication
(10) Pub. No.: US 2025/0023004 A1
(43) Pub. Date: Jan. 16, 2025

(54) LIGHT EMITTING DEVICE PACKAGE AND SURFACE LIGHT SOURCE DEVICE INCLUDING THE SAME

(71) Applicant: SANSUNG ELECTRONICS CO., LTD., Suwon-si (KR)

(72) Inventors: Jungsung KIM, Suwon-si (KR); Jinkweon Jung, Suwon-si (KR); Sunhwan Hwang, Suwon-si (KR); Daesup Kim, Suwon-si (KR); Sangbok Yun, Suwon-si (KR)

(73) Assignee: SANSUNG ELECTRONICS CO., LTD., Suwon-si (KR)

(21) Appl. No.: 18/765,986

(22) Filed: Jul. 8, 2024

(30) Foreign Application Priority Data
Jul. 12, 2023 (KR) 10-2023-0090672
Feb. 13, 2024 (KR) 10-2024-0020658

(51) Int. Cl. H01L 33/62; H01L 25/075; H01L 33/50; H01L 33/58

(52) U.S. Cl. CPC H01L 33/62; H01L 25/0753; H01L 33/502; H01L 33/58

(57) ABSTRACT

A light emitting device package may include a wiring substrate. The wiring substrate may include: a first wiring electrode; a second wiring electrode; an insulating support supporting the first wiring electrode and the second wiring electrode; and a surface from which the first wiring electrode and the second wiring electrode are exposed. a semiconductor light emitting device disposed on the surface of the wiring substrate. The light emitting device package may further include: a first scattering layer covering the semiconductor light emitting device, on the surface of the wiring substrate; and a second scattering layer disposed on the first scattering layer. For light emitted from the semiconductor light emitting device, a maximum intensity of a first directional light in a 0-degree direction may be less than a maximum intensity of a second directional light in a 45-degree direction.

### CROSS-REFERENCE TO RELATED APPLICATIONS

This application is based on and claims priority under 35 U.S.C. § 119 to Korean Patent Application Nos. 10-2023-0090672, filed on Jul. 12, 2023, and 10-2024-0020658, filed on Feb. 13, 2024, in the Korean Intellectual Property Office, the disclosures of which are incorporated by reference herein in their entirety.

### BACKGROUND

### 1. Field

The disclosure relates to a light emitting device package and a surface light source device including the same. Specifically, the disclosure relates to a light emitting device package including a scattering layer and a surface light source device including the same.

### 2. Description of Related Art

Light emitting device packages are widely used as light sources because they have several advantages such as: low power consumption, high brightness, and long lifespan. On the other hand, it is desirable that surface light source devices including such a light emitting device package have uniform brightness and high power efficiency. A commonly used method to increase a beam angle of light emitted from light emitting device packages is to use a separate lens. The beam angle may be increased by arranging a convex diffusion lens on an upper portion of a light emitting device package, but in this case, it may be difficult to reduce the thickness of a surface light source device due to the additional diffusion lens.

### SUMMARY

Example embodiments of the disclosure provide a light emitting device package with a large beam angle and a small size compared to the amount of light and a surface light source device including the light emitting device package and having uniform brightness, high power efficiency, and a degree of freedom in thickness design.

The problems to be solved by the disclosure are not limited to the above-mentioned problems, and other problems not mentioned will be clearly understood by those skilled in the art from the following description.

According to one or more example embodiments, a light emitting device package may include a wiring substrate. The wiring substrate may include: a first wiring electrode; a second wiring electrode; an insulating support supporting the first wiring electrode and the second wiring electrode; and a surface from which the first wiring electrode and the second wiring electrode are exposed. a semiconductor light emitting device disposed on the surface of the wiring substrate. The light emitting device package may further include: a first scattering layer covering the semiconductor light emitting device, on the surface of the wiring substrate; and a second scattering layer disposed on the first scattering layer. For light emitted from the semiconductor light emitting device, a maximum intensity of a first directional light in a 0-degree direction may be less than a maximum intensity of a second directional light in a 45-degree direction, where the 0-degree direction and the 45-degree direction are in a plane parallel to the surface of the wiring substrate.

A thickness of the light emitting device package may be 1600 μm or less.

A thickness of the first scattering layer may be 500 μm to 1200 μm.

A thickness of the second scattering layer may be 50 μm to 400 μm.

A thickness of the wiring substrate may be 0.1 mm to 0.4 mm.

A reflectance of the second scattering layer may be 3% or more.

The maximum intensity of the first directional light may be 60% or more of the maximum intensity of the second directional light.

An intensity of light of the light emitting device package may be an optical axis direction is 40% or more but less than 100% of the maximum intensity of the first directional light.

The first scattering layer may include a first transparent material and a first scattering material, and a refractive index of the first scattering material may be about 1.4 to about 2.8.

The first scattering material may include a scattering material or a wavelength conversion material.

The second scattering layer may include a second transparent material and a second scattering material, and the second scattering material may include particles of a material having a refractive index of about 1.4 to about 3.0.

The second scattering material may include titanium oxide (TiO₂), and a content ratio of the second scattering material in the second scattering layer may exceed 0% and be 60% or less.

The refractive index of the first scattering material and a refractive index of the second scattering material may be different from each other.

A thickness of the second scattering layer may be about 50 μm to about 400 μm.

A diffusion lens may not be on the semiconductor light emitting device.

According to one or more example embodiments, a light emitting device package may include a wiring substrate. The wiring substrate may include: a first wiring electrode; a second wiring electrode; an insulating support supporting the first wiring electrode and the second wiring electrode; and a surface from which the first wiring electrode and the second wiring electrode are exposed. The light emitting device package may further include: a plurality of semiconductor light emitting devices disposed on the surface of the wiring substrate; and a scattering layer covering the plurality of semiconductor light emitting devices, on the surface of the wiring substrate. For light emitted from the plurality of semiconductor light emitting devices, a maximum intensity of a first directional light in a 0-degree direction may be less than a maximum intensity of a second directional light in a 45-degree direction, where the 0-degree direction and the 45-degree direction are in a plane parallel to the surface of the wiring substrate.

The maximum intensity of the first directional light may be 60% or more of the maximum intensity of the second directional light.

According to one or more example embodiments, a surface light source device may include: a module substrate; a plurality of light emitting device packages disposed on the module substrate; and a diffusion plate separated from the module substrate by an optical distance. One light emitting device package of the plurality of light emitting device packages may include: a wiring substrate. The wiring substrate may include: a first wiring electrode; a second wiring electrode; an insulating support supporting the first wiring electrode and the second wiring electrode; and a surface from which the first wiring electrode and the second wiring electrode are exposed. The one light emitting device package may include: a semiconductor light emitting device disposed on the surface of the wiring substrate; a first scattering layer covering the semiconductor light emitting device, on the surface of the wiring substrate; and a second scattering layer disposed on the first scattering layer. For light emitted from the semiconductor light emitting device, a maximum intensity of a first directional light in a 0-degree direction may be less than a maximum intensity of a second directional light in a 45-degree direction, where the 0-degree direction and the 45-degree direction are in a plane parallel to the surface of the wiring substrate.

A uniformity of luminance measured on the diffusion plate may be 90% or more.

The maximum intensity of the first directional light may be 60% or more of the maximum intensity of the second directional light.

### BRIEF DESCRIPTION OF THE DRAWINGS

The above and other aspects, features, and advantages of the disclosure will be more clearly understood from the following detailed description, taken in conjunction with the accompanying drawings, in which:

FIG. 1A is a perspective view showing a light emitting device package according to one or more embodiments;

FIG. 1B is a top view showing one or more embodiments of the light emitting device package shown in FIG. 1A in a Z-axis direction;

FIG. 2 is a graph showing light distribution characteristics of one or more embodiments of the light emitting device package shown in FIG. 1A;

FIG. 3A is a perspective view showing a light emitting device package according to one or more embodiments;

FIG. 3B is a top view showing one or more embodiments of the light emitting device package shown in FIG. 3A in a Z-axis direction;

FIG. 4A is a schematic top perspective view of a surface light source device according to one or more embodiments;

FIG. 4B is a cross-sectional view of one or more embodiments of the surface light source device shown in FIG. 4A taken along a line I-I′;

FIG. 5 is an image illustrating an upper surface of a surface light source device in an operating state, according to one or more embodiments;

FIG. 6A is a view illustrating the intensity of light according to a position on a light emitting surface of a surface light source device according to one or more embodiments; and

FIG. 6B is a graph illustrating the intensity of light according to the position on a line II-II′ on the light emitting surface of one or more embodiments of the surface light source device shown in FIG. 6A.

### DETAILED DESCRIPTION

A central axis of a light emitting device is called an optical axis. An optical axis of a light source is a central axis of light that is emitted. A direction in which light travels is defined as a positive (+) direction of the optical axis. In the case of a light emitting device or a light emitting device package, the optical axis may be defined based on a structure. In general, the optical axis corresponds to a light emitting direction perpendicular to the light emitting surface from the center of the light emitting surface. In addition, a short axis may correspond to a direction of a shortest distance from the center of the light emitting surface to a side end of the light emitting device, perpendicular to the optical axis.

In the specification, unless otherwise defined, a Z-axis is defined as an axis parallel to the optical axis, an X-axis is defined as an axis parallel to the short axis, and a Y-axis is defined as an axis perpendicular to each of the Z-axis and the X-axis. An angle between a certain direction and a positive direction of the Z-axis is defined as a polar angle. In addition, when a certain direction is projected onto an X-Y plane, a rotation angle clockwise from the positive direction of the X-axis with respect to the Z-axis is defined as an azimuthal angle.

Hereinafter, embodiments of the disclosure will be described in detail with reference to the accompanying drawings. The same reference numerals are used for the same components in the drawings, and redundant descriptions thereof are omitted.

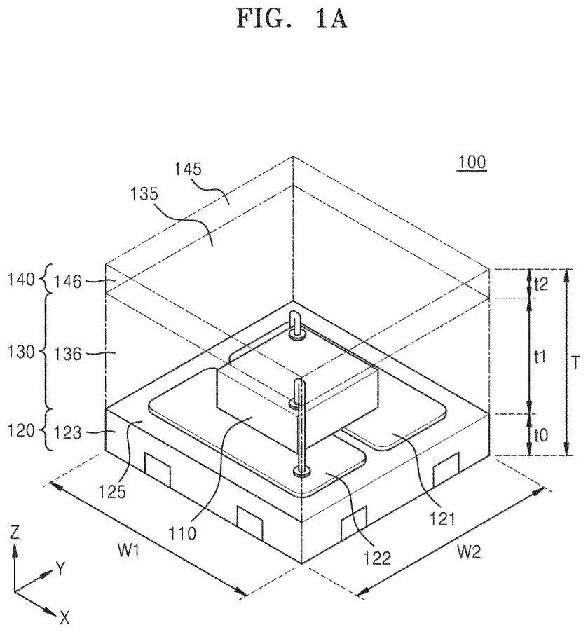

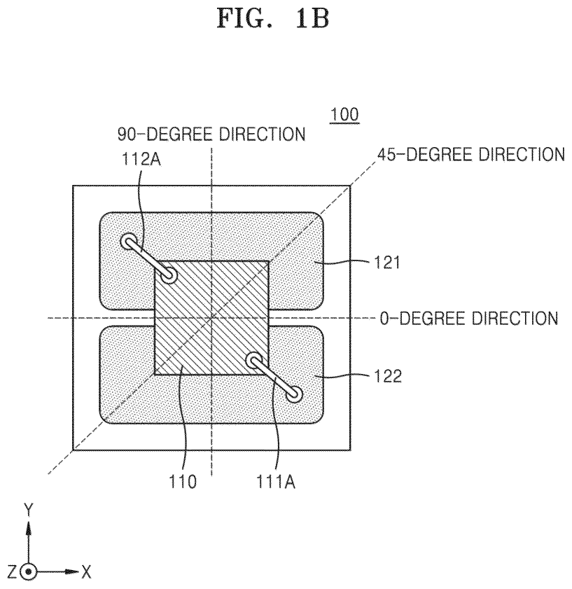

FIG. 1A is a perspective view showing a light emitting device package 100 according to one or more embodiments. FIG. 1B is a top view showing one or more embodiments of the light emitting device package 100 shown in FIG. 1A in a Z-axis direction.

Referring to FIGS. 1A and 1B together, the light emitting device package 100 may include a wiring substrate 120 including a mounting surface 125, a semiconductor light emitting device 110 mounted on the mounting surface 125 of the wiring substrate 120, and a first scattering layer 130 covering the semiconductor light emitting device 110 on the wiring substrate 120.

Here, a total height T of the light emitting device package 100 may be 1600 μm or less, and a first width W1 and a second width W2 each may be about 1.0 mm to about 2.4 mm.

The wiring substrate 120 may have a thickness t0 of about 0.1 mm to about 0.4 mm. In some embodiments, the wiring substrate 120 may have the thickness t0 of about 0.2 mm to about 0.3 mm.

The wiring substrate 120 may include a first wiring electrode 121 and a second wiring electrode 122 and an insulating support 123 supporting the first wiring electrode 121 and the second wiring electrode 122, and a part of each of the first wiring electrode 121 and the second wiring electrode 122 may be located on the mounting surface 125.

The insulating support 123 may include an opaque resin or a resin having a high reflectance. For example, the insulating support 123 may include a resin including a highly reflective material (e.g., TiO₂, SiO₂, and Al₂O₃) in powder form. In some embodiments, the insulating support 123 may include ceramic capable of easily dissipating heat.

In some embodiments, the insulating support 123 may be in the form of a substrate that provides a plane supporting lower surfaces of the first wiring electrode 121 and the second wiring electrode 122. In some embodiments, the insulating support 123 may be in contact with side surfaces of the first wiring electrode 121 and the second wiring electrode 122. In some embodiments, the insulating support 123 may be formed through injection molding.

In some embodiments, the first wiring electrode 121 and the second wiring electrode 122 may be located on the insulating support 123. The first wiring electrode 121 and the second wiring electrode 122 may be electrically connected to the semiconductor light emitting device 110. In the drawings, the first wiring electrode 121 and the second wiring electrode 122 and the semiconductor light emitting device 110 are electrically connected through wire bonding using a first wire 111A and a second wire 112A, but are not limited to this configuration. In some embodiments, in the case of a flip chip in which an electrode of the semiconductor light emitting device 110 is disposed on the lower surface, the semiconductor light emitting device 110 and the first wiring electrode 121 and the second wiring electrode 122 may be electrically connected to each other through a solder ball.

The first scattering layer 130 may include a first side surface 136 surrounding the semiconductor light emitting device 110 and a substantially flat first upper surface 135. The first side surface 136 and the first upper surface 135 may be light emitting surfaces. The first scattering layer 130 may include a first transparent material and a first scattering material disposed therein. The first transparent material may be, for example, a transparent resin such as transparent silicon. The first scattering material may have a refractive index of about 1.4 to about 2.8. The first scattering material may be, for example, a scattering material such as SiO₂, SiN, Al₂O₃, TiO₂, etc. or a wavelength conversion material such as a phosphor, a quantum dot, etc. When the first scattering material includes the wavelength conversion material, part of light of a first wavelength emitted from the semiconductor light emitting device 110 may be converted into light of a second wavelength shorter than the first wavelength by the wavelength conversion material.

A ratio of the area of the first side surface 136 to the area of the first upper surface 135 of the first scattering layer 130 may be about 32% to about 120%, and in some embodiments, may be about 32% to about 80%. When the ratio of the area of the first side surface 136 to the area of the first upper surface 135 of the first scattering layer 130 increases, the amount of light reflected from the first upper surface 135 and absorbed in the light emitting device package 100 increases, thereby reducing efficiency. Alternatively, when the ratio of the area of the first side surface 136 to the area of the first upper surface 135 of the first scattering layer 130 decreases, the light emitting device package 100 has an unstable structure.

Here, the area of the first side surface 136 means the entire area of the first side surface 136. For example, when the first scattering layer 130 has a rectangular parallelepiped shape and has four surfaces with different directions between the first upper surface 135 and the first lower surface, the area of the first side surface 136 means the sum of the areas of the four surfaces.

A thickness t1 of the first scattering layer 130 may be about 0.31 times to about 0.75 times the first width W1 and the second width W2 of the light emitting device package 100. Specifically, when the size of the light emitting device package 100 is about 1.6 mmx about 1.6 mm, the thickness t1 of the first scattering layer 130 may be about 500 μm to about 1200 μm. As the thickness t1 of the first scattering layer 130 increases, the speed of light transmission therethrough may decrease.

In some embodiments, the light emitting device package 100 may further include a second scattering layer 140 disposed on the first scattering layer 130.

The second scattering layer 140 may be designed to have a reflectance of 3% or more in the air. In this case, more light may be distributed to the side surface of the light emitting device package 100.

The second scattering layer 140 may include a second transparent material and a second scattering material. The second scattering material may be particles including a material having a refractive index of about 1.4 to about 3.0. For example, the second scattering material may be TiO₂. In this case, a content ratio of the second scattering material in the second scattering layer 140 may be greater than 0% and less than or equal to 60%. In some embodiments, the content ratio of the second scattering material in the second scattering layer 140 may be about 5% to about 60%.

In some embodiments, a refractive index of the first scattering material may be different from a refractive index of the second scattering material. That is, the first scattering material and the second scattering material may be different materials.

A thickness t2 of the second scattering layer 140 may be about 50 μm to about 400 μm. The thickness t2 of the second scattering layer 140 may vary according to a refractive index of the second transparent material, a refractive index of the second scattering material, a particle size of the second scattering material, a concentration of the second scattering material, etc. Like the first scattering layer 130, light is relatively suppressed from emitting in the direction of the second upper surface 145 of the second scattering layer 140, and is induced to emit in the direction of the second side surface 146, thereby increasing a light beam angle.

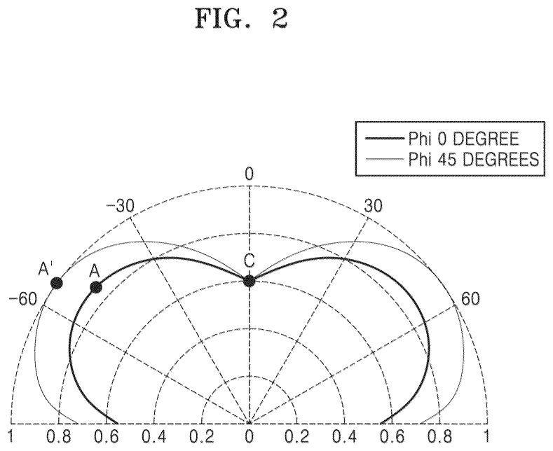

FIG. 2 is a graph showing light distribution characteristics of the light emitting device package 100 shown in FIG. 1A.

FIGS. 2 and 1A together show an intensity of light emitted from the light emitting device package 100 according to a light emitting direction, that is, an intensity of directional light. FIGS. 2 and 1A together show the intensity of light according to a 0-degree direction and a 45-degree direction of the light emitting device package 100.

A rotation direction with respect to an optical axis of the light emitting device package 100 is referred to as an azimuthal angle, and the azimuthal angle may be indicated with respect to a short axis direction of the light emitting device package 100. The 0-degree direction and the 45-degree direction may be in a plane parallel to the surface of the wiring substrate 120.

FIGS. 2 and 1A together show the intensity of light emitted when an angle, i.e. a polar angle, between the optical axis and a light emitting direction changes from −90 degrees to +90 degrees with respect to each of the 0-degree direction and the 45-degree direction of the light emitting device package 100, i.e., the azimuth angle of 0 degree (Pi 0 degree) and the azimuth angle of 45 degrees (Pi 45 degrees).

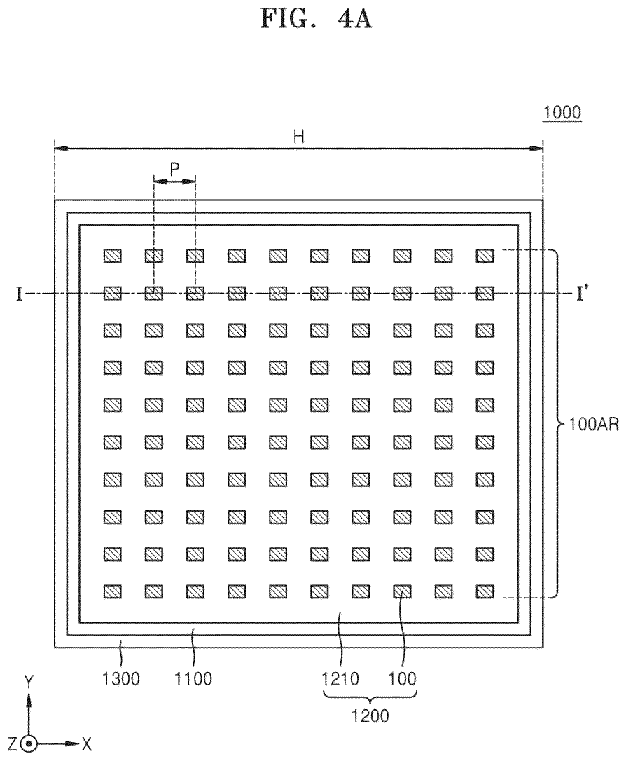

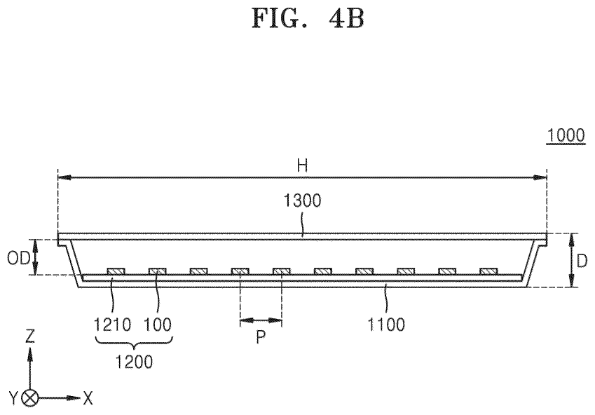

In case where the intensity of light in the 0-degree direction and the 90-degree direction is relatively lower than the intensity of light in a diagonal direction in the light emitting device package 100, when a plurality of light emitting device packages 100 are disposed in a matrix form, the uniformity of intensity of light of a surface light source device 1000 (see FIG. 4A) may be increased.

In some embodiments, a maximum intensity A of the directional light (first directional light) in the 0-degree direction may be less than a maximum intensity A′ of the directional light (second directional light) in the 45-degree direction. That is, A/A′ may be less than 100%. Here, A/A′ may be 70% or more for the surface light source device 1000 for lighting, and 60% or more for the surface light source device 1000 for display, but is not limited thereto.

In some embodiments, an intensity C of light of the light emitting device package 100 in the optical axis direction may be 40% or more and less than 100% of the maximum intensity A of the directional light (first directional light) in the 0-degree direction. Here, in the case of the light emitting device package 100 for the surface light source device 1000 for a display, C/A may be 40% or more and less than 100%. In the case of the light emitting device package 100 for the surface light source device 1000 for lighting, C/A may be 70% or more and less than 100%, but is not limited thereto.

As described above, by utilizing the disclosure, the light emitting device package 100 with a wide beam angle may be implemented without a separate optical component (e.g., a diffusion lens). In addition, by utilizing the light emitting device package 100 of the disclosure, occupied space is smaller than when using the separate optical component, and thus, applications to various instruments are possible and a set configuration is possible at low cost.

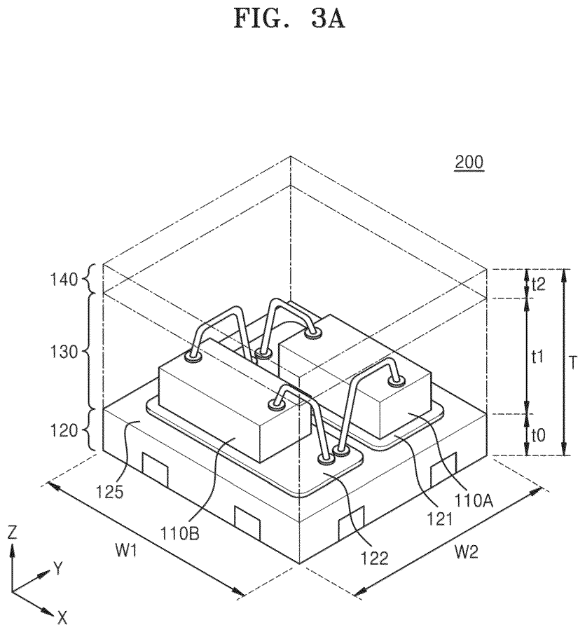

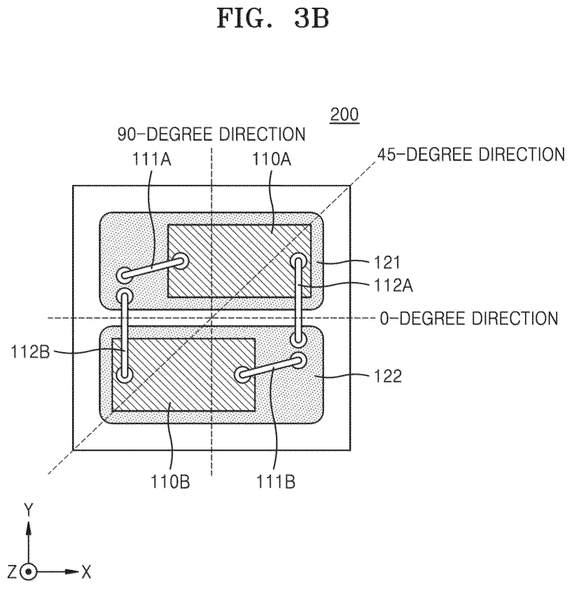

FIG. 3A is a perspective view showing a light emitting device package 200 according to one or more embodiments. FIG. 3B is a top view showing the light emitting device package 200 shown in FIG. 3A in a Z-axis direction.

Most of components of the light emitting device package 200 described below and materials of the components are substantially the same as or similar to those described with reference to FIGS. 1A and 1B. Therefore, for convenience of description, differences from the light emitting device package 100 described above are mainly described.

Referring to FIGS. 3A and 3B together, the light emitting device package 200 may include the wiring substrate 120 including the mounting surface 125, a first semiconductor light emitting device 110A and a second semiconductor light emitting device 110B mounted on the mounting surface 125 of the wiring substrate 120, and a first scattering layer 130 disposed on the wiring substrate 120 and covering the first semiconductor light emitting device 110A and the second semiconductor light emitting device 110B.

The light emitting device package 200 may include the first semiconductor light emitting device 110A and the second semiconductor light emitting device 110B. That is, the light emitting device package 200 may include a plurality of semiconductor light emitting devices. As described above, when the light emitting device package 200 includes the first semiconductor light emitting device 110A and the second semiconductor light emitting device 110B, the first semiconductor light emitting device 110A and the second semiconductor light emitting device 110B may be rotated within 45 degrees from each other to prevent light absorption. Alternatively, the first semiconductor light emitting device 110A and the second semiconductor light emitting device 110B may be parallel to each other to prevent light absorption, but may be disposed to cross 10% or more of a length of one side in the first semiconductor light emitting device 110A and the second semiconductor light emitting device 110B.

In some embodiments, the first wiring electrode 121 and the second wiring electrode 122 and the first semiconductor light emitting device 110A may be electrically connected to each other by wire bonding through the first wire 111A and the second wire 112A, and the first wiring electrode 121 and the second wiring electrode 122 and the second semiconductor light emitting device 110B may be electrically connected to each other by wire bonding through a third wire 111B and a fourth wire 112B.

FIG. 4A is a schematic top perspective view of the surface light source device 1000 according to one or more embodiments. FIG. 4B is a cross-sectional view of the surface light source device 1000 shown in FIG. 4A taken along a line I-I′.

Referring to FIGS. 4A and 4B together, the surface light source device 1000 includes a light emitting device array 100AR and a diffusion plate 1300.

A plurality of light emitting device packages 100 constituting the light emitting device array 100AR may be disposed in a housing 1100 to have a certain pitch P. The pitch P means a distance between centers of the neighboring light emitting device packages 100.

The light emitting device array 100AR may include a module substrate 1210 and a light emitting device module 1200 including a plurality of light emitting device packages 100 mounted on the module substrate 1210. In some embodiments, the light emitting device array 100AR may include a plurality of light emitting device modules 1200. The module substrate 1210 and the diffusion plate 1300 are disposed to be spaced apart by a certain distance, and the distance is referred to as an optical distance OD. A ratio P/OD between the optical distance OD of the surface light source device 1000 and the pitch P of the light emitting device array 100AR may be less than 2.0.

Light emitted from the diffusion plate 1300 may be used as a surface light source. The surface light source device 1000 may be a general lighting product or a backlight unit of a display device. The light emitting device package 100 included in the surface light source device 1000 may be the light emitting device package 100 or the light emitting device package 200 according to the above-described embodiments.

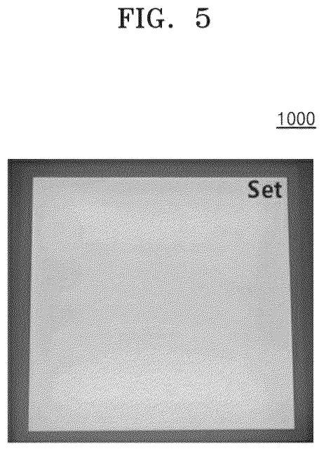

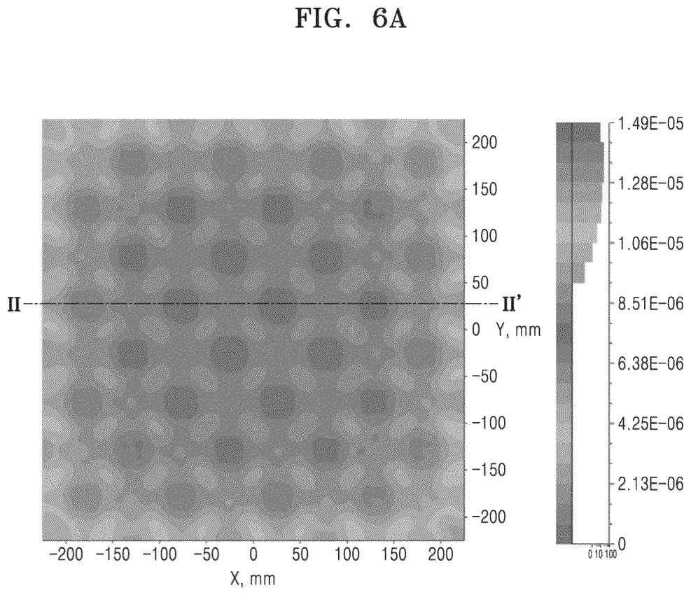

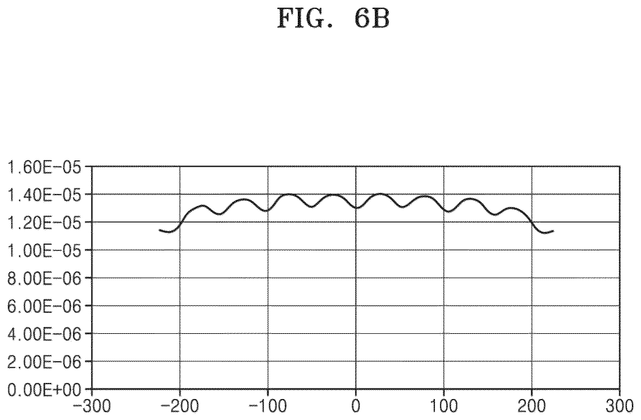

FIG. 5 is an image illustrating an upper surface of the surface light source device 1000 in an operating state according to one or more embodiments. FIG. 6A is a view illustrating the intensity of light according to a position on a light emitting surface of the surface light source device 1000 according to one or more embodiments. FIG. 6B is a graph illustrating the intensity of light according to the position on a line II-II′ on the light emitting surface of the surface light source device 1000 shown in FIG. 6A.

FIGS. 5, 6A, and 6B together show an intensity of light emitted from the surface light source device 1000 and a uniformity of light.

The intensity of light and the uniformity of light are important factors that determine the quality of the surface light source device 1000. The uniformity of light on an upper surface of the diffusion plate 1300 (see FIG. 4B), which is the light emitting surface of the surface light source device 1000, may be expressed as a ratio of intensity C of light in a bright part and intensity D of light in a dark part, and the uniformity of light may be 90% or more. In this case, an edge region of the light emitting surface is excluded.

As may be seen from images and graphs, by utilizing the disclosure, the high-quality surface light source device 1000 may be implemented using the light emitting device package 100 (see FIG. 4B) with a wide directional angle without a separate optical component (e.g., a diffusion lens).

While certain embodiments of the disclosure has been particularly shown and described, it will be understood that various changes in form and details may be made therein without departing from the spirit and scope of the following claims.

What is claimed is:

1. A light emitting device package comprising:
a wiring substrate comprising:
a first wiring electrode;
a second wiring electrode;
an insulating support supporting the first wiring electrode and the second wiring electrode; and
a surface from which the first wiring electrode and the second wiring electrode are exposed;
a semiconductor light emitting device disposed on the surface of the wiring substrate;
a first scattering layer covering the semiconductor light emitting device, on the surface of the wiring substrate; and
a second scattering layer disposed on the first scattering layer,
wherein for light emitted from the semiconductor light emitting device, a maximum intensity of a first directional light in a 0-degree direction is less than a maximum intensity of a second directional light in a 45-degree direction, where the 0-degree direction and the 45-degree direction are in a plane parallel to the surface of the wiring substrate.

2. The light emitting device package of claim 1, wherein a thickness of the light emitting device package is 1600 μm or less.

3. The light emitting device package of claim 1, wherein a thickness of the first scattering layer is 500 μm to 1200 μm.

4. The light emitting device package of claim 1, wherein a thickness of the second scattering layer is 50 μm to 400 μm.

5. The light emitting device package of claim 1, wherein a thickness of the wiring substrate is 0.1 mm to 0.4 mm.

6. The light emitting device package of claim 1, wherein a reflectance of the second scattering layer is 3% or more.

7. The light emitting device package of claim 1, wherein the maximum intensity of the first directional light is 60% or more of the maximum intensity of the second directional light.

8. The light emitting device package of claim 1, wherein an intensity of light of the light emitting device package in an optical axis direction is 40% or more but less than 100% of the maximum intensity of the first directional light.

9. The light emitting device package of claim 1, wherein
the first scattering layer comprises a first transparent material and a first scattering material, and
a refractive index of the first scattering material is about 1.4 to about 2.8.

10. The light emitting device package of claim 9, wherein the first scattering material comprising a scattering material or a wavelength conversion material.

11. The light emitting device package of claim 10, wherein
the second scattering layer comprises a second transparent material and a second scattering material, and
the second scattering material comprises particles of a material having a refractive index of about 1.4 to about 3.0.

12. The light emitting device package of claim 11, wherein
the second scattering material comprises titanium oxide (TiO₂), and
a content ratio of the second scattering material in the second scattering layer exceeds 0% and is 60% or less.

13. The light emitting device package of claim 11, wherein the refractive index of the first scattering material and a refractive index of the second scattering material are different from each other.

14. The light emitting device package of claim 12, wherein a thickness of the second scattering layer is about 50 μm to about 400 μm.

15. The light emitting device package of claim 1, wherein a diffusion lens is not on the semiconductor light emitting device.

16. A light emitting device package comprising:
a wiring substrate comprising:
a first wiring electrode;
a second wiring electrode;
an insulating support supporting the first wiring electrode and the second wiring electrode; and
a surface from which the first wiring electrode and the second wiring electrode are exposed;
a plurality of semiconductor light emitting devices disposed on the surface of the wiring substrate; and
a scattering layer covering the plurality of semiconductor light emitting devices, on the surface of the wiring substrate,
wherein for light emitted from the plurality of semiconductor light emitting devices, a maximum intensity of a first directional light in a 0-degree direction is less than a maximum intensity of a second directional light in a 45-degree direction, where the 0-degree direction and the 45-degree direction are in a plane parallel to the surface of the wiring substrate.

17. The light emitting device package of claim 16, wherein the maximum intensity of the first directional light is 60% or more of the maximum intensity of the second directional light.

18. A surface light source device comprising:
a module substrate;
a plurality of light emitting device packages disposed on the module substrate; and
a diffusion plate separated from the module substrate by an optical distance,
wherein one light emitting device package of the plurality of light emitting device packages comprises:
a wiring substrate comprising:
a first wiring electrode;
a second wiring electrode;
an insulating support supporting the first wiring electrode and the second wiring electrode; and
a surface from which the first wiring electrode and the second wiring electrode are exposed;
a semiconductor light emitting device disposed on the surface of the wiring substrate;
a first scattering layer covering the semiconductor light emitting device, on the surface of the wiring substrate; and
a second scattering layer disposed on the first scattering layer, and
wherein for light emitted from the semiconductor light emitting device, a maximum intensity of a first directional light in a 0-degree direction is less than a maximum intensity of a second directional light in a 45-degree direction, where the 0-degree direction and the 45-degree direction are in a plane parallel to the surface of the wiring substrate.

19. The surface light source device of claim 18, wherein a uniformity of luminance measured on the diffusion plate is 90% or more.

20. The surface light source device of claim 18, wherein the maximum intensity of the first directional light is 60% or more of the maximum intensity of the second directional light.
